(19) United States
(12) Patent Application Publication
(10) Pub. No.: US 2022/0148844 A1
(43) Pub. Date: May 12, 2022

(54) COMPOSITE SOLENOID MAGNETIC LENS

(71) Applicant: Imatrex, Inc., Las Vegas, NV (US)

(72) Inventors: Roy E. Rand, Portola Valley, CA (US); Seth Z. Kalson, Las Vegas, NV (US)

(21) Appl. No.: 17/095,380

(22) Filed: Nov. 11, 2020

(51) Int. Cl. H01J 37/141; H01F 7/08; H01F 7/126

(52) U.S. Cl. CPC H01J 37/1413; H01J 2237/1405; H01F 7/126; H01F 7/081

(57) ABSTRACT

Magnetic lens having two or more distinct and separate, detachable assemblies, at least one of the detachable assemblies having a core about which a solenoid is wound so that the solenoid need not be wound or unwound when the assemblies are attached or de-attached.

### BACKGROUND

A solenoid magnetic lens is used to focus a beam of charged particles traveling inside an evacuated tube. A conventional solenoid magnetic lens comprises a solenoid wound around a cylindrically-shaped core having high magnetic permeability. The cylindrically-shaped core fits around the evacuated tube, and includes a narrow slit. A current source energizes the solenoid to generate a magnetic field. The narrow slit allows the magnetic field to penetrate into the evacuated tube, thereby focusing the beam of charged particles traveling inside the evacuated tube. Applications include electron microscopes, linear accelerators, X-ray generators, and electron beam computed tomography scanners.

When assembling or servicing a system with a solenoid magnetic lens, it may be necessary to dismantle flanges on the tube in order to install or remove the solenoid magnetic lens. Alternatively, the solenoid may be wound or unwound to install or remove it. In another example, a flange connects two sections of a tube, and a solenoid magnetic thin lens surrounds the tube rendering its flange inaccessible. To access the flange, a service technician unwinds the solenoid about the core, and the core is dissembled and removed from the tube to allow access to the flange. The procedure is reversed to assemble or reassemble the solenoid magnetic thin lens about the tube. Winding or unwinding the solenoid in situ is time consuming, contributing to design and labor costs when assembling or servicing the system.

### SUMMARY

Some embodiments may be described as follows.

In an embodiment, a magnetic lens comprises: a first assembly comprising a first pole piece having a cylindrical surface sector, a second pole piece having a cylindrical surface sector, and a core; a first solenoid wound on the core of the first assembly; and a second assembly comprising a first pole piece having a cylindrical surface sector, and a second pole piece having cylindrical surface sector; wherein the first and second assemblies are detachable from each other. Further in the embodiment, the first and second assemblies each comprise a high magnetic permeability material. Further in the embodiment, the cylindrical surface sectors of the first and second pole pieces of the first assembly, and the cylindrical surface sectors of the first and second pole pieces of the second assembly, each have a same radius of curvature. Further in the embodiment, the magnetic lens further comprises a latching mechanism to facilitate attaching the first and second assemblies to each other and de-attaching the first and second assemblies from each other. Further in the embodiment, a first non-magnetic gap separates the cylindrical surface sectors of the first and second pole pieces of the first assembly, a second non-magnetic gap separates the cylindrical surface sectors of the first and second pole pieces of the second assembly, and the first and second gaps align with each other when the first and second assemblies are attached to each other. Further in the embodiment, the cylindrical surface sectors of the first and second pole pieces of the first assembly and the cylindrical surface sectors of the first and second pole pieces of the second assembly share a common axis of symmetry when the first and second assemblies are attached to each other. Further in the embodiment, the first solenoid includes no turns around the cylindrical surface sectors of the first and second pole pieces of the first assembly. Further in the embodiment, the second assembly comprises a core, and the magnetic lens further comprises a second solenoid wound on the core of the second assembly.

In another embodiment, a system comprises: a tube; a source of charged particles attached to the tube; and a magnetic lens surrounding a portion of the tube, the magnetic lens comprising: a first assembly comprising a first pole piece having a cylindrical surface sector, a second pole piece having a cylindrical surface sector, and a core; a first solenoid wound on the core of the first assembly; and a second assembly comprising a first pole piece having a cylindrical surface sector, and a second pole piece having cylindrical surface sector. Further in the embodiment, a first non-magnetic gap separates the cylindrical surface sectors of the first and second pole pieces of the first assembly; a second non-magnetic gap separates the cylindrical surface sectors of the first and second pole pieces of the second assembly; and the first and second gaps align with each other. Further in the embodiment, the first solenoid includes no turns around the cylindrical surface sectors of the first and second pole pieces of the first assembly. Further in the embodiment, the second assembly comprises a core, and the magnetic lens further comprises: a second solenoid wound on the core of the second assembly, wherein the second solenoid includes no turns around the cylindrical surface sectors of the first and second pole pieces of the second assembly.

In another embodiment, a magnetic lens comprises: a plurality of assemblies, each assembly comprising a first pole piece having a cylindrical surface sector, a second pole piece having a cylindrical surface sector, and a core; a plurality of solenoids in correspondence to the plurality of assemblies, each solenoid wound around the core of its corresponding assembly; and a latching mechanism to attach together the plurality of assemblies and to de-attach the plurality of assemblies from each other. Further in the embodiment, each cylindrical surface sector has a same radius of curvature. Further in the embodiment, the magnetic lens further comprises: a plurality of non-magnetic gaps in correspondence with the plurality of assemblies, each non-magnetic gap separating the cylindrical surface sectors of its corresponding assembly. Further in the embodiment, the plurality of non-magnetic gaps align with each other when the latching mechanism attaches the plurality of assemblies to each other. Further in the embodiment, each cylindrical surface sector subtends a same angle. Further in the embodiment, the angles subtended by each cylindrical surface sector sum to 360°. Further in the embodiment, each cylindrical surface sector has a same radius of curvature. Further in the embodiment, each solenoid includes no turns around the cylindrical surface sectors of the first and second pole pieces of its corresponding assembly.

### BRIEF DESCRIPTION OF THE DRAWINGS

FIG. 1 illustrates a double solenoid magnetic lens according to embodiments.

FIG. 2 illustrates a triple solenoid magnetic lens according to embodiments.

FIG. 3 illustrates a single solenoid magnetic lens according to embodiments.

### DETAILED DESCRIPTION OF EMBODIMENTS

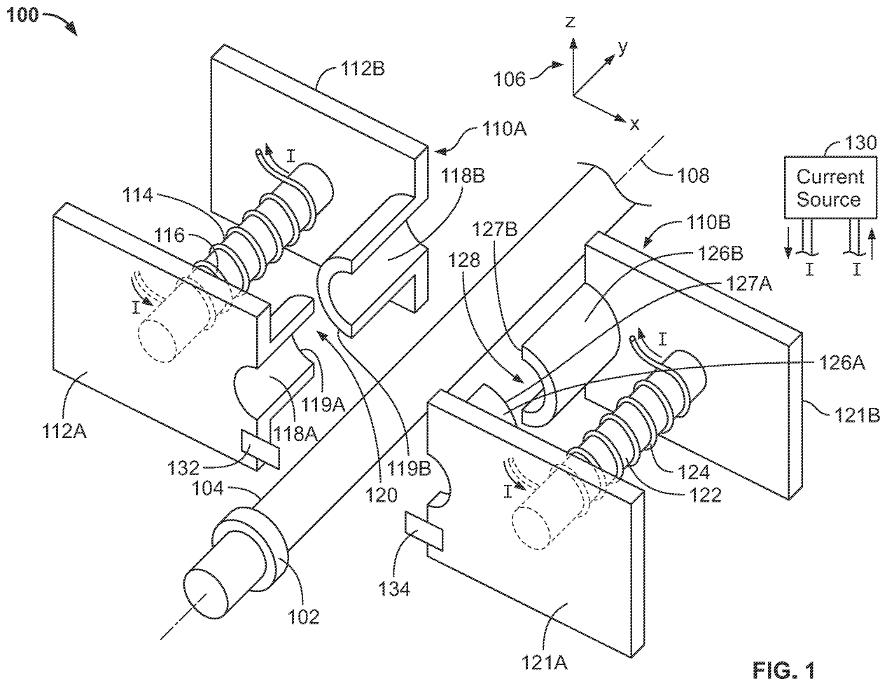

FIG. 1 shows an isometric view of a system, System 100, according to some embodiments. FIG. 1 is simplified and not drawn to scale, and illustrates only those components of System 100 required to sufficiently describe embodiments.

System 100 comprises a source of charged particles, Charged Particle Source 102. The charged particles may be electrons. Charged Particle Source 102 is attached to a tube, Tube 104, which is evacuated when operating System 100. Referring to a reference coordinate system, Coordinate System 106, the charged particles are accelerated so as to travel through Tube 104, along its axis (shown as a dashed line and labeled 108), in the direction of the y-axis of Coordinate System 106. In some embodiments, Charged Particle Source 102 accelerates the charged particles, and in some embodiments, other additional structures (not shown) employ electric or magnetic fields to further accelerate the charged particles.

The solenoid magnetic lens illustrated in FIG. 1 comprises two assemblies, Assembly 110A and Assemblyl10B. Assembly 110A is described first.

Assembly 110A comprises a first pole piece, Pole Piece 112A, and a second pole piece, Pole Piece 112B, each comprising a material having high magnetic permeability. Assembly 110A comprises a core, Core 114, and a solenoid, Solenoid 116, wound around Core 114. For ease of illustration, Solenoid 116 is shown with only a few, sparsely spaced windings about Core 114, but in practice Solenoid 116 usually comprises a relatively large number of windings, wound tightly about Core 114, with adjacent windings spaced closely to one another.

Core 114 may comprise a material having high magnetic permeability. Core 114 may be solid or hollow inside. Core 114 is shown to have a cylindrical shape, but this is not necessary. Assembly 110A may be manufactured so that Core 114 and Pole Pieces 112A and 112B together comprise an integrated component of System 100; or, as a another example, Assembly 110A may be manufactured such that Core 114 and Pole Pieces 112A and 112B are separate components that are assembled together.

Pole Piece 112A includes a surface, denoted by 118A and referred to as the cylindrical surface sector 118A. The cylindrical surface sector 118A is a concave surface of Pole Piece 112A and may be described as a sector of a cylindrical surface, the sector subtending 180°. In some embodiments, the cylindrical surface sector 118A may subtend an angle other than 180°. An edge 119A of the cylindrical surface sector 118A is perpendicular to the axis of the cylindrical surface sector 118A. The cylindrical surface sector 118A has a radius of curvature equal to or greater than the outer radius of Tube 104.

Pole Piece 112B includes a surface, denoted by 118B and referred to as the cylindrical surface sector 118B. The above remarks regarding the cylindrical surface sector 118A of Pole Piece 112A are applicable to the cylindrical surface sector 118B of Pole Piece 112B, and not all details need be repeated. An edge 119B of the cylindrical surface sector 118B is perpendicular to the axis of the cylindrical surface sector 118B. The cylindrical surface sectors 118A and 118B each have the same axis and radius of curvature. Core 114 is shown to be substantially parallel to the axis of the cylindrical surface sectors 118A and 118B, although this is not necessary.

A gap 120 separates the two cylindrical surface sectors 118A and 118B from each other. The gap 120 presents a non-magnetic spacing between the two cylindrical surface sectors 118A and 118B of Pole Pieces 112A and 112B, respectively, and may, for example, be an air gap or comprise a non-magnetic (low magnetic permeability) material. Accordingly, the gap 120, as well as the other gaps that will be described in the description of embodiments, may be termed or described as non-magnetic gaps.

Referring now to Assembly 110B, its description is essentially the same as that of Assembly 110A, and not all details need be repeated. Assembly 110B comprises a first pole piece, Pole Piece 121A, a second pole piece, Pole Piece 121B, a core, Core 122, and a solenoid, Solenoid 124, wound around Core 122. Pole Pieces 121A and 121B each comprise a material having high magnetic permeability, and Core 122 may comprise a material having high magnetic permeability. Core 122 may be solid or hollow inside. Pole Pieces 121A and 121B include, respectively, surfaces denoted and referred to as the cylindrical surface sectors 126A and 126B, each subtending 180°. An edge 127A of the cylindrical surface sector 126A is perpendicular to the axis of the cylindrical surface sector 126A, and an edge 127B of the cylindrical surface sector 126B is perpendicular to the axis of the cylindrical surface sector 126B. A gap 128 separates the edges 127A and 127B.

In some embodiments, Assemblies 110A and 110B may be mirror images of each other, although this is not necessary.

FIG. 1 shows Assemblies 110A and 110B detached from each other. To form a solenoid magnetic lens, the two assemblies are attached to each other so that their respective cylindrical surface sectors surround Tube 104. When Assemblies 110A and 110B are attached to each other, the cylindrical surface sectors 118A and 126A, in combination, surround Tube 104, and the cylindrical surface sectors 118B and 126B, in combination, surround Tube 104, with the gaps 120 and 128 aligned to one another to effectively provide a small slit or gap surrounding Tube 104, so that the combination of the attached Assemblies 110A and 110B forms a solenoid magnetic lens. In some embodiments, the cylindrical surface sectors 118A, 118B, 126A, and 126B are in physical contact with Tube 104 when Assemblies 110A and 110B are attached to each other.

Solenoids 116 and 124 are wound about their respective cores in such a way that, when the two assemblies are attached to each other, and when the solenoids are driven by a current source, Current Source 130, the generated magnetic field is symmetrical with respect to the y-axis of Coordinate System 106, and within Tube 104, the generated magnetic field has radial symmetry. One may refer to the generated magnetic field within Tube 104 as the focusing field. Depending upon the way in which the solenoids are coupled to Current Source 130, the solenoids need not be mirror images of each other. That is, their windings need not have the same sense of direction.

In the embodiment of FIG. 1, the windings of each solenoid are wound counterclockwise when looking along the y-axis, with each solenoid coupled to Current Source 130 so that their respective currents have a counterclockwise direction when looking along the y-axis, where the arrows labeled “I” denote the direction of current. In other embodiments, one solenoid is wound counterclockwise and the other is wound clockwise, but their respective currents are sourced so that their magnetic fields are symmetrical about the y-axis. That is, the solenoids in an embodiment are driven so that their respective currents have the same sense of direction.

In the example of FIG. 1, a single current source, Current Source 130, drives both solenoids. In some embodiments, two current sources may be employed, each one driving a corresponding solenoid.

Each assembly includes one or more attaching mechanisms to facilitate attaching and detaching the assemblies to and from each other, so as to bring them close to (or in contact with) Tube 104. For example, an attaching mechanism denoted by 132 mates to an attaching mechanism denoted by 134. It is not necessary to describe in detail these attaching mechanisms to sufficiently describe embodiments. For ease of illustration, only two attaching mechanisms are shown, but in practice more than two attaching mechanisms may be employed at various positions on the assemblies. In some embodiments, one assembly may have a male-type attaching mechanism and the other a female-type attaching mechanism so that they may mate to each other. (In such embodiments, the assemblies cannot strictly be mirror images of each other.)

The radii of curvature for the cylindrical surface sectors 118A, 118B, 126A, and 126B are equal to each other. With Assemblies 110A and 110B attached to each other, their respective cylindrical surface sectors share a common axis of symmetry, and their respective gaps are aligned. Normally, this axis of symmetry coincides with the axis 108 of Tube 104. By attaching Assembly 110A to Assembly 110B, a magnetic lens is formed about Tube 104. The resulting magnetic lens can be termed a multiple solenoid magnetic lens or a double solenoid magnetic lens. If the gaps 120 and 128 are relatively thin, then the resulting magnetic lens is a thin lens.

If Tube 104 is cylindrical, then for some embodiments the radii of curvature for the cylindrical surface sectors 118A, 118B, 126A, and 126B of Assemblies 110A and 110B are each equal to the radius of Tube 104. Tube 104 need not be cylindrical in shape.

Because Assemblies 110A and 110B are separate and distinct, detachable structures, and because the solenoids are not wound around the cylindrical surface sectors, Assemblies 110A and 110B can be attached to and detached from each other with their respective solenoids intact. Assembling or dissembling the magnetic lens can be accomplished without winding or unwinding the solenoids. Accordingly, having the solenoids wound around their respective cores, where the cylindrical surface sectors of the pole pieces are separate and distinct from the cores, and where the solenoids have no turns about the cylindrical surface sectors of the pole pieces, leads to improved serviceability of System 100 in the field.

For embodiments, Assemblies 110A and 110B each comprise a material having a relatively high magnetic permeability. Assemblies 110A and 110B may include laminated sections to mitigate losses due to eddy currents. The magnetic field H generated by the solenoids has its greatest magnitude within the gap 120 between Pole Pieces 112A and 112B, and within the gap 128 of Pole Pieces 121A and 121B. When Assemblies 110A and 110B are attached to each other, and when Current Source 130 drives Solenoids 116 and 124, the magnetic field H inside Tube 104 within the vicinity of the gaps 120 and 128 (the focusing field) is similar to that of a single solenoid wound around a single core having a gap and surrounding Tube 104. The focusing field has radial symmetry about the axis 108 of Tube 104.

Embodiments may be described using magnetic circuit terminology. Assemblies 110A and 110B each comprise material having a relatively small reluctance, and in particular, the pole pieces have small reluctance. Solenoid 116, when energized, holds Pole Piece 112A at a different magnetic potential than that of Pole Piece 112B. Similarly, Solenoid 124, when energized, holds Pole Piece 121A at a different magnetic potential than that of Pole Piece 121B. With Assemblies 110A and 110B assembled together to form a magnetic lens, Pole Pieces 112A and 121A are coupled together so as to be at the same magnetic potential, and Pole Pieces 112B and 121B are coupled together so as to be at the same magnetic potential. It is thus to be understood that assembling, coupling, or attaching together Assemblies 110A and 110B includes bringing them together by way of physical contact with each other, or coupling them together by way of a low reluctance (high magnetic permeability) path, so that Pole Pieces 112A and 121A are at the same magnetic potential, and Pole Pieces 112B and 121B are at the same magnetic potential.

Each pole piece provides a low reluctance path so that with Assemblies 110A and 110B assembled together to form a magnetic lens and with the solenoids energized, the magnetomotive force drop is largest across the gaps (line integral of H along a path in the gap), so that the magnetic field H is strongest in the vicinity of the gaps.

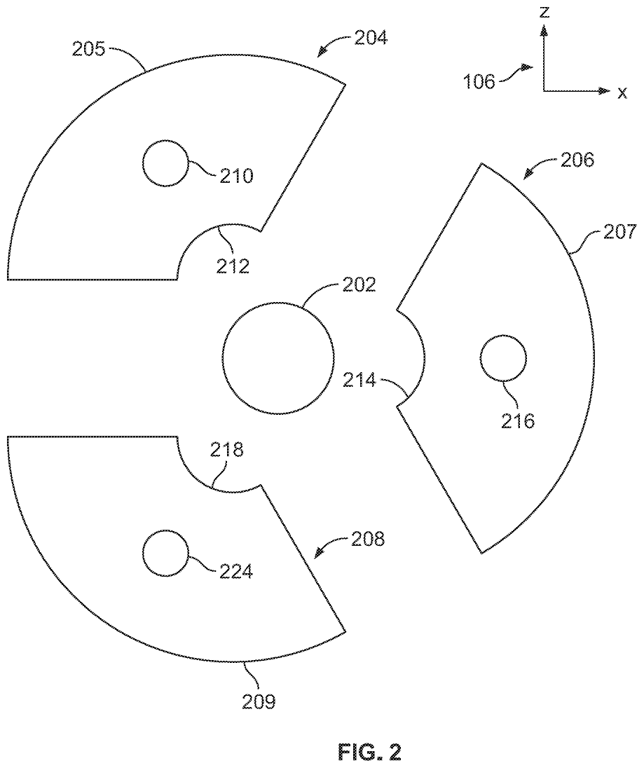

Some embodiments may utilize more than two assemblies and solenoids. FIG. 2 illustrates a cross-sectional view of a triple solenoid magnetic lens, with the view taken as a slice perpendicular to the y-axis of Coordinate System 106 (this coordinate system is shown in both FIG. 1 and FIG. 2), where for FIG. 2 the y-axis points into the drawing sheet. FIG. 2 is simplified and not drawn to scale, and illustrates only those components required to sufficiently describe embodiments. As its name implies, the magnetic lens of FIG. 2 comprises three solenoids, not shown for ease of illustration. A tube, Tube 202, in which charged particles can travel, has an axis aligned with the y-axis of Coordinate System 106. Three assemblies are illustrated: Assemblies 204, 206, and 208.

Assembly 204 includes a pole piece, Pole Piece 205, and a core, Core 210, about which a first solenoid (not shown) is wound. Pole Piece 205 has a cylindrical surface sector 212. Assembly 206 includes a pole piece, Pole Piece 207, and a core, Core 216, about which a second solenoid (not shown) is wound. Pole Piece 207 has a cylindrical surface sector 214. Assembly 208 includes a pole piece, Pole Piece 208, and a core, Core 224, about which a third solenoid (not shown) is wound. Pole Piece 208 has a cylindrical surface sector 218. Because the drawing of FIG. 2 represents a cross-sectional slice of an embodiment, with the view perpendicular to the y-axis of Coordinate 106, the drawing does not reveal the other pole pieces of the assemblies and their respective cylindrical surface sectors. Furthermore, the gaps between the cylindrical surface sectors are not shown. However, the description of these structures and features not shown in FIG. 2 are readily apparent in light of the description of FIG. 1.

Each assembly is a distinct separate structure, detachable from the other assemblies. Each cylindrical surface sector subtends 120° and has a same radius of curvature. Attaching mechanisms (not shown) facilitate attaching and detaching the assemblies. When Assemblies 204, 206, and 208 are attached together, their respective cylindrical surface sectors form a cylindrically-shaped structure about Tube 202, and their respective gaps are aligned. Each assembly comprises a high magnetic permeability material so that their respective solenoids, when energized, generate a magnetic field H, with largest magnitude in the vicinity of the gaps. The resulting magnetic lens generates a focusing field similar to that of a single solenoid wound around a single core having a gap.

Extending the embodiments of FIG. 1 and FIG. 2 to an embodiment with an arbitrary number of assemblies and solenoids is straightforward to describe, and easily follows by considering the embodiments of FIG. 1 and FIG. 2. In general, a multiple solenoid magnetic lens comprises a plurality of distinct and separate, detachable assemblies, each assembly having two pole pieces separated by a gap, and a core about which a solenoid is wound. Attaching mechanisms allow the assemblies to be attached and detached to one another. Each pole piece has a cylindrical surface sector with a same radius of curvature. When the assemblies are attached together, their respective gaps are aligned, and their respective cylindrical surface sectors have a common axis. When the solenoids are energized, the resulting magnetic field in the vicinity of the gaps is similar to that of a single solenoid wound about a single core having a gap.

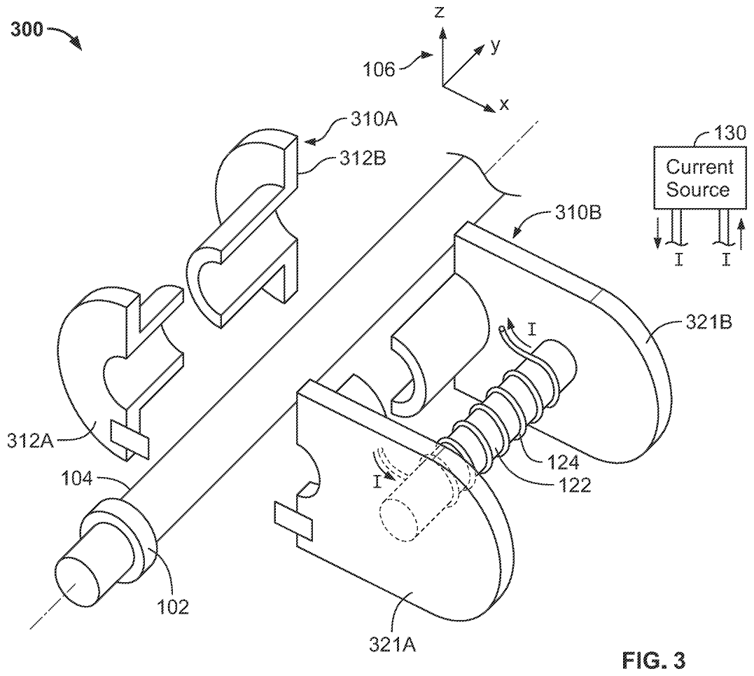

FIG. 3 shows an isometric view of a system, System 300, according to some embodiments. FIG. 3 is simplified and not drawn to scale, and illustrates only those components of System 300 required to sufficiently describe embodiments. Because of the similarities between FIG. 1 and FIG. 3, much of the description for the embodiment of FIG. 1 is applicable to that of FIG. 3. and need not be repeated. For reference, when comparing FIG. 3 to FIG. 1, FIG. 3 shows Coordinate System 106, Charged Particle Source 102, Tube 104, Core 122, and Solenoid 124.

The differences between FIG. 1 and FIG. 3 are readily apparent. Assembly 310A comprises two pole pieces, Pole Piece 312A and Pole Piece 312B, but does not include a core and solenoid. Assembly 310B comprises two pole pieces, Pole Piece 321A and Pole Piece 321B, Core 122, and Solenoid 124. Each pole piece in the embodiment of FIG. 3 has cylindrical surface sectors similar to that of FIG. 1, and their detailed descriptions need not be repeated. The assemblies shown in FIG. 3 are not mirror images of each other, and do not have the same form factor as that of FIG. 1. Showing the assemblies of FIG. 3 with different form factors than that of FIG. 1 merely serves to illustrate that embodiments may have assemblies of various sizes and shapes.

As for the embodiments of FIG. 1 and FIG. 2, Assemblies 310A and 310B in FIG. 3 are attached to each other to form a solenoid magnetic lens about Tube 104. It is expected that the single solenoid magnetic lens of FIG. 3 generates a focusing field similar to that of a multiple solenoid magnetic lens (e.g., FIG. 1 or FIG. 2), provided that Assemblies 310A and 310B have sufficiently large magnetic susceptibility and any unwanted magnetomotive force drops across their respective interfaces are sufficiently small. However, it may be supposed that, in practice, a multiple solenoid magnetic lens achieves a focusing field truer to that of an ideal solenoid magnetic lens than that of an embodiment according to FIG. 3 employing only one solenoid.

Although not shown in FIG. 3, a non-magnetic structure may be employed to secure Pole Pieces 312A and 312B when Assembly 310A is detached from Assembly 310B.

Relating a measurable aspect of an embodiment (e.g., length, angle, time) to a numerical value, or relating by an equality or equivalence a measurable aspect of an embodiment to another measurable aspect, is accurate to within accepted tolerances as practiced in the relevant art; accordingly, the qualifier “substantially” or the like for a numerical quantity or relationship is not needed when describing embodiments or reciting a claim element.

What is claimed is:

1. A magnetic lens comprising:
a first assembly comprising a first pole piece having a cylindrical surface sector, a second pole piece having a cylindrical surface sector, and a core;
a first solenoid wound on the core of the first assembly; and
a second assembly comprising a first pole piece having a cylindrical surface sector, and a second pole piece having cylindrical surface sector;
wherein the first and second assemblies are detachable from each other.

2. The magnetic lens as set forth in claim 1, the first and second assemblies each comprising a high magnetic permeability material.

3. The magnetic lens as set forth in claim 1, wherein the cylindrical surface sectors of the first and second pole pieces of the first assembly, and the cylindrical surface sectors of the first and second pole pieces of the second assembly, each have a same radius of curvature.

4. The magnetic lens as set forth in claim 1, further comprising:
a latching mechanism to facilitate attaching the first and second assemblies to each other and de-attaching the first and second assemblies from each other.

5. The magnetic lens as set forth in claim 1, wherein
a first non-magnetic gap separates the cylindrical surface sectors of the first and second pole pieces of the first assembly;
a second non-magnetic gap separates the cylindrical surface sectors of the first and second pole pieces of the second assembly; and
the first and second gaps align with each other when the first and second assemblies are attached to each other.

6. The magnetic lens as set forth in claim 5, wherein
the cylindrical surface sectors of the first and second pole pieces of the first assembly and the cylindrical surface sectors of the first and second pole pieces of the second assembly share a common axis of symmetry when the first and second assemblies are attached to each other.

7. The magnetic lens as set forth in claim 1, wherein the first solenoid includes no turns around the cylindrical surface sectors of the first and second pole pieces of the first assembly.

8. The magnetic lens as set forth in claim 1, the second assembly comprising a core, the magnetic lens further comprising:
a second solenoid wound on the core of the second assembly.

9. A system comprising:
a tube;
a source of charged particles attached to the tube; and
a magnetic lens surrounding a portion of the tube, the magnetic lens comprising:
a first assembly comprising a first pole piece having a cylindrical surface sector, a second pole piece having a cylindrical surface sector, and a core;
a first solenoid wound on the core of the first assembly; and
a second assembly comprising a first pole piece having a cylindrical surface sector, and a second pole piece having cylindrical surface sector.

10. The system as set forth in claim 9, wherein
a first non-magnetic gap separates the cylindrical surface sectors of the first and second pole pieces of the first assembly;
a second non-magnetic gap separates the cylindrical surface sectors of the first and second pole pieces of the second assembly; and
the first and second gaps align with each other.

11. The system as set forth in claim 10, wherein the first solenoid includes no turns around the cylindrical surface sectors of the first and second pole pieces of the first assembly.

12. The system as set forth in claim 11, the second assembly comprising a core, the magnetic lens further comprising:
a second solenoid wound on the core of the second assembly, wherein the second solenoid includes no turns around the cylindrical surface sectors of the first and second pole pieces of the second assembly.

13. A magnetic lens comprising:
a plurality of assemblies, each assembly comprising a first pole piece having a cylindrical surface sector, a second pole piece having a cylindrical surface sector, and a core;
a plurality of solenoids in correspondence to the plurality of assemblies, each solenoid wound around the core of its corresponding assembly; and
a latching mechanism to attach together the plurality of assemblies and to de-attach the plurality of assemblies from each other.

14. The magnetic lens as set forth in claim 13, wherein each cylindrical surface sector has a same radius of curvature.

15. The magnetic lens as set forth in claim 13, further comprising:
a plurality of non-magnetic gaps in correspondence with the plurality of assemblies, each non-magnetic gap separating the cylindrical surface sectors of its corresponding assembly.

16. The magnetic lens as set forth in claim 15, wherein the plurality of non-magnetic gaps align with each other when the latching mechanism attaches the plurality of assemblies to each other.

17. The magnetic lens as set forth in claim 16, wherein each cylindrical surface sector subtends a same angle.

18. The magnetic lens as set forth in claim 17, wherein the angles subtended by each cylindrical surface sector sum to 360°.

19. The magnetic lens as set forth in claim 18, wherein each cylindrical surface sector has a same radius of curvature.

20. The magnetic lens as set forth in claim 19, wherein each solenoid includes no turns around the cylindrical surface sectors of the first and second pole pieces of its corresponding assembly.
